(19) United States
(12) Patent Application Publication
(10) Pub. No.: US 2004/0166447 A1
(43) Pub. Date: Aug. 26, 2004

(54) Method for shrinking pattern photoresist

(76) Inventors: Vencent Chang, Taipei City (TW); Chia-Chen Chen, Hsin-Chu City (TW); George Liu, Ping-Cheng City (TW); Benjamin Szu-Min Lin, Hsin-Chu City (TW); Cheng-Chung Chen, Tao-Yuan City (TW)

Correspondence Address: Nath & Associates, PLLC, Sixth Floor, 1030 15th Street, N.W., Washington, DC, 20005, US

(21) Appl. No.: 10/373,099

(22) Filed: Feb. 26, 2003

(51) Int. Cl. G03F 7/40; G03F 7/26

(52) U.S. Cl. 430/324; 430/315; 430/330

(57) ABSTRACT

First of all, a semiconductor substrate with a photoresist layer thereon is provided. Then a plurality of pattern photoresists with a first line width are formed on the semiconductor substrate by a photolithography process. Next, an acid-process is performed to form a diffusion layer having the acid-based materials on the plurality of pattern photoresists and the semiconductor substrate. Afterward, a re-baking process is performed to diffuse the acid-based materials within diffusion layer into the plurality of pattern photoresists such that the acid-based materials chain-react with the plurality of pattern photoresist located on the diffusion depth of the acid-based materials so as to form a plurality of reaction layers within the skin layers of the plurality of pattern photoresists, wherein the diffusion depth of the acid-based materials in the plurality of pattern photoresists depends on the diffuse rate of the acid-based materials in the acid-process. Subsequently, a redeveloping process is performed to remove the plurality of reaction layers so as to form a plurality of the pattern photoresists with a second line width on the semiconductor substrate. Furthermore, all processes disclosed as above are performed in in-situ environment.

### BACKGROUND OF THE INVENTION

1. Field of the Invention

The present invention relates generally to a method for controlling the critical dimension (CD) of semiconductor process, and more particularly to a method for shrinking the critical dimension of the pattern photoresist.

2. Description of the Prior Art

As semiconductor devices, such as the Metal-Oxide-Semiconductor device, become highly integrated the area occupied by the device shrinks, as well as the design rule. With advances in the semiconductor technology, the dimensions of the integrated circuit(IC) devices have shrunk to the deep sub-micron range. When the semiconductor device continuously shrinks in the deep sub-micron region, some problems described below are incurred due to the scaling down process. To enlarge the litho-window, the thickness of the photoresist layer has to be decreased. In the photolithography fabrication which transfers pattern on mask into photoresist, the step of development is used to develop the pattern in the photoresist which has been baked and exposed. Whereby, developer is used to partial of photoresist which does not correspond to any pattern, and then only partial photoresist which corresponds to the pattern is reserved. In general, after pattern on mask has been transferred into photoresist which located on surface layer, which locates on substrate, photoresist is divided into two parts: pattern photoresist which corresponds to pattern, and non-pattern photoresist which corresponds to nothing. In the Next step, developer is distributed, by the spray/puddle way or other ways, on photoresist to let every part of photoresist is covered by developer. Then, uses positive photoresist as example, pattern photoresist is removed by developer and then only non-pattern photoresist is reserved. Thus, reserved non-pattern photoresist could be used to define required pattern in underlying surface layer in following processes such as etch. Certainly, although shown example is positive photoresist, same action is appeared for negative photoresist.

The evolution of integrated circuits has evolved such that scaling down the device geometry is required. In the deep sub-micron technology of semiconductors, it's necessary that the line width of the pattern photoresist is trimmed to be narrow, so as to obtain the semiconductor with the smaller dimensions. Conventional process for trimming the line width of the pattern photoresist utilizes an etching process to shrink the critical dimension of, after finishing the exposure and development process. In general, the etching process for shrinking pattern photoresist is an isotropy etching process, and this process cannot trim the structure in profile of pattern photoresist, so that the critical dimension uniformity within the pattern photoresist cannot be maintained. Additionally, another process is a trimming process with plasma that utilizes a plasma process with anisotropy electron beam to perform the etching process so as to shrink the pattern photoresist. Regarding treating the pattern photoresist with this process, its vertical etching rate will be larger than the horizontal etching rate thereof, so that top of the pattern photoresist will be over lost when the predetermined critical dimension thereof have not achieved yet, and thickness of the pattern photoresist is over thin after trimming the line width to become the predetermined critical dimension; and further, when the pattern photoresist formed by the trimming process with plasma acts as an etching mask or an ion-implanting mask to perform the follow-up etching process or ion-implanting process, the gate oxide layer is usually etched thoroughly into the substrate at the main endpoint or the pattern photoresist is easily punctured by ions. On the other hand, any conventional process for trimming the pattern photoresist can not control the structure in profile, it is very difficult to avoid the problem of line edge roughness (LER), and all these prior arts have to proceed with the etching process in ex-situ environment, so that the process rate not only becomes be slow to prolong the process cycle time, but also the process cost will be increased.

However, controlling the critical dimension is very important in the below deep sub-micron region. Especially, when the design rule is scaled down, the line width is reduced to be narrower, resulting in shrinkage of the pattern photoresist more difficult to control or retain as critical dimension requires. If pattern photoresist's profile can not be completely maintained, it will greatly affect the follow-up implanting process or etching process, and a possible shift in electricity will reduce the performance of the device. In accordance with the above description, a new and improved method for shrinking the critical dimension of the pattern photoresist is therefore necessary, so as to raise the yield and quality of the follow-up process.

### SUMMARY OF THE INVENTION

In accordance with the present invention, a method is provided that substantially overcomes the drawbacks of the above mentioned problems when shrinking the critical dimension of the pattern photoresist by using existing conventional methods.

Accordingly, it is one of objects in the present invention to provide a process for shrinking the pattern photoresist. This invention can utilize an acid-process to form a diffusion layer within the skin layer of the pattern photoresist after finishing the photolithography process, wherein the acid-process of the present invention can control the chain reaction by way of the diffuse rate of the acid-based material, so as to achieve the purpose for shrinking the pattern photoresist. Furthermore, this invention can perform a chain reaction with the pattern photoresist and the acid-based material within the diffusion layer by way of using a re-baking process to transform the polarity of the pattern photoresist and form a reaction layer after finishing the acid-process, wherein the present invention can control the profile of the reaction layer by way of the controlling factors of the re-baking process to influence the critical dimension of the pattern photoresist, so the line width of that can be free biased. Moreover, this invention also can remove the reaction layer by way of using a redeveloping process to form the pattern photoresist with a line width smaller than the original line width formed by prior photolithography process after finishing the re-baking process. As disclosed as above, the process of the present invention for shrinking the pattern photoresist can not only maintain the integrity profile of the pattern photoresist but also avoid the problem of line edge roughness (LER); and further, this invention can perform all process in in-situ environment to proceed with the process for shrinking the pattern photoresist so as to accelerate the process rate and reduce the process cycle time. Therefore, this invention can reduce the costs of the conventional process and hence correspond to economic effect, and that is appropriate for deep sub-micron technology when providing semiconductor devices.

In accordance with the present invention, a new method for shrinking the pattern photoresist is disclosed. First of all, a semiconductor substrate with a photoresist layer thereon is provided. Then a plurality of pattern photoresists with a first line width are formed on the semiconductor substrate by a photolithography process. Next, an acid-process is performed to form a diffusion layer having the acid-based materials on the plurality of pattern photoresists and the semiconductor substrate. Afterward, a re-baking process is performed to diffuse the acid-based materials within diffusion layer into the plurality of pattern photoresists such that the acid-based materials chain-react with the plurality of pattern photoresist located on the diffusion depth of the acid-based materials so as to form a plurality of reaction layers within the skin layers of the plurality of pattern photoresists, wherein the diffusion depth of the acid-based materials in the plurality of pattern photoresists depends on the diffuse rate of the acid-based materials in the acid-process. Subsequently, a redeveloping process is performed to remove the plurality of reaction layers so as to form a plurality of the pattern photoresists with a second line width on the semiconductor substrate. Furthermore, all processes disclosed as above are performed in in-situ environment.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 show cross-sectional views illustrative of various stages for shrinking the line width of the pattern photoresist by way of using a new process in accordance with the first embodiment of the present invention;

FIG.2 show cross-sectional views illustrative of various stages for shrinking the line width of the pattern photoresist by way of using a new process in accordance with the second embodiment of the present invention; and

FIG.3 show cross-sectional views illustrative of various stages for shrinking the line width of the pattern photoresist by way of using a new process in accordance with the third embodiment of the present invention;

### DESCRIPTION OF THE PREFERRED EMBODIMENT

These preferred embodiments of the present invention are now described in greater detail. Nevertheless, it should be recognized that the present invention can be practiced in a wide range of other embodiments besides those explicitly described, and the scope of the present invention is expressly not limited except as specified in the accompanying claims.

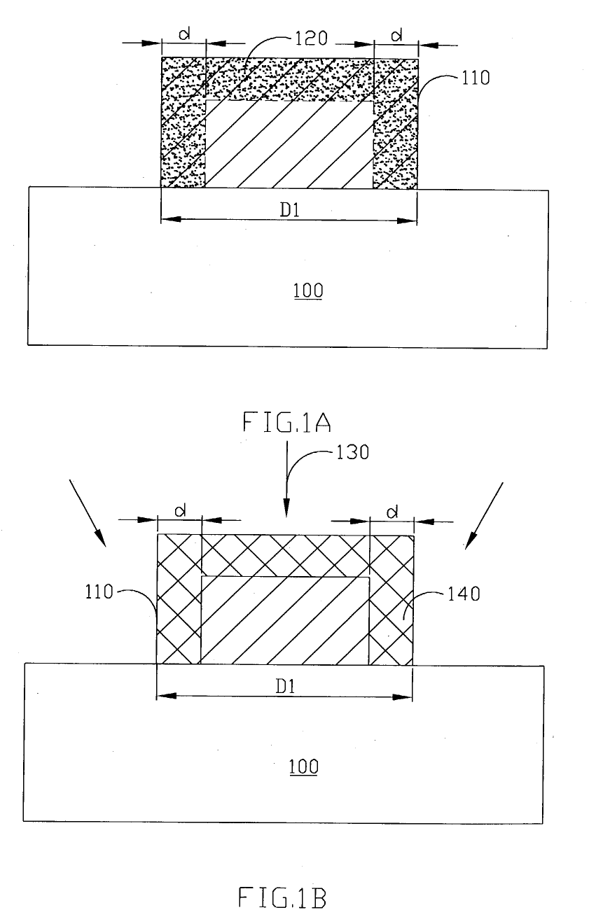

As illustrated in FIG. 1A to FIG. 1C, in the first embodiment of the present invention, first of all, a semiconductor substrate 100 having a pattern photoresist 110 with a first line width D1 thereon is provided. Then a chemical diffusion layer 120 is anisotropicly formed on the pattern photoresist 110 by using a chemical material. Afterward, a baking process 130 is performed to diffuse the chemical material within the chemical diffusion layer 120 into the pattern photoresist 110 such that the chemical material reacts with the pattern photoresist 110 located on the diffusion depth d of the chemical material to form a chemical reaction layer 140 within the skin layer of the pattern photoresist 110, wherein the diffusion depth d of the chemical material in the pattern photoresist 110 depends on the diffuse rate of the chemical material. Subsequently, a developing process 150 is performed to remove the chemical reaction layer 140 so as to trim the first line width D1 to a second line width D2 of the pattern photoresist 110 on the semiconductor substrate 100, wherein the difference in line width between the first line width D1 and the second line width D2 there is the diffusion depth d of the chemical diffusion layer 120 in the pattern photoresist 110. Furthermore, all processes in the first embodiment disclosed as above are performed in the in-situ environment.

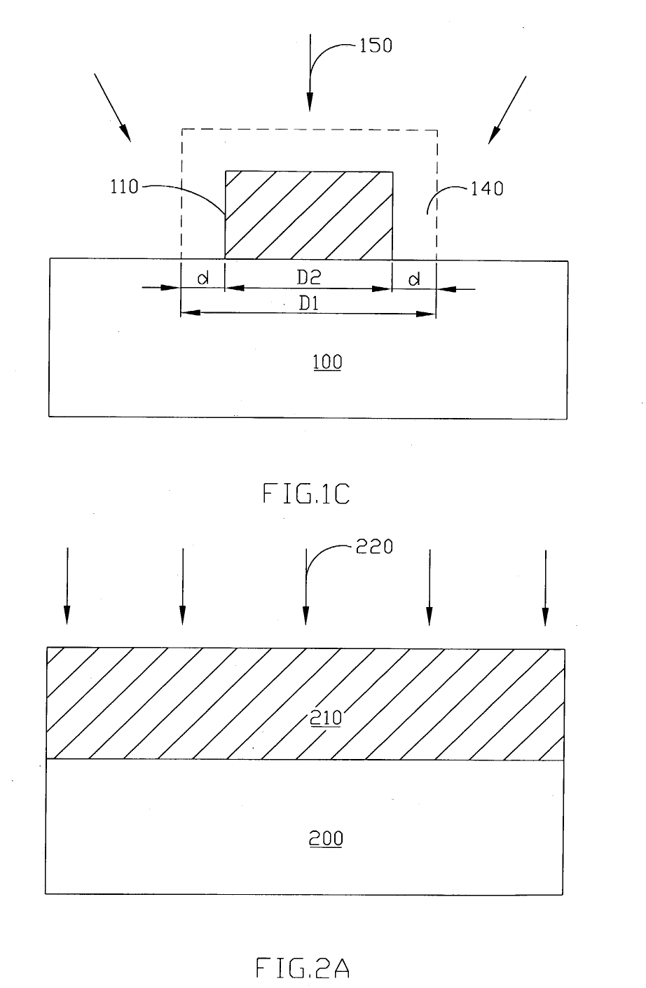

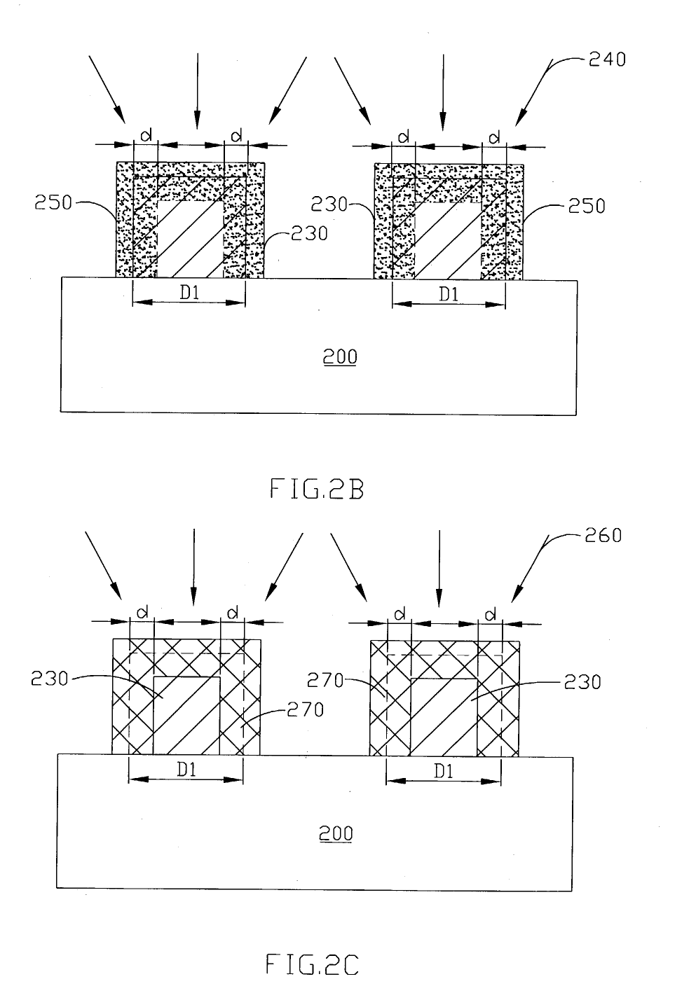

As illustrated in FIG. 2A to FIG. 2D, in the second embodiment of the present invention, first of all, a semiconductor substrate 200 is provided, wherein a photoresist layer 210 having a first chemical polarity is formed on the semiconductor substrate 200. Then performing a photolithography process 220 is to form a plurality of pattern photoresists 230 with a first line width D1 on the semiconductor substrate 200. After forming the plurality of pattern photoresists 230, an acid-process 240 is performed to form a plurality of diffusion layers 250 on the plurality of pattern photoresists 230, so as to diffuse acid-based materials of the acid-process 240 from the plurality of diffusion layers 250 into the plurality of pattern photoresists 230, wherein the acid-based materials utilized in the acid-process 240 can transform the first chemical polarity into the second chemical polarity, and the diffusion depth d of the acid-based materials in the plurality of pattern photoresists 230 depend on the diffuse rate of the acid-based materials. Afterward, a baking process 260 is performed to defuse the acid-based materials from the plurality of diffusion layers 250 into the plurality of pattern photoresists 230 such that the acid-based materials react with the plurality of pattern photoresists 230 located on the diffusion depth d of the acid-based materials to form a plurality of reaction layer 270 with the second chemical polarity in the skin layer of the plurality of pattern photoresists 230. Subsequently, a developing process 280 is performed to remove the plurality of reaction layer 270, so as to trim the first line width D1 to a second line width D2 of the plurality of pattern photoresists 230 on the semiconductor substrate 200, wherein the difference in line width between the first line width D1 and the second line width D2 there is the diffusion depth d in the plurality of, pattern photoresists 230, and the developing process 280 comprises a developer with the second chemical polarity. Furthermore, all processes in the second embodiment disclosed as above are performed in the in-situ environment.

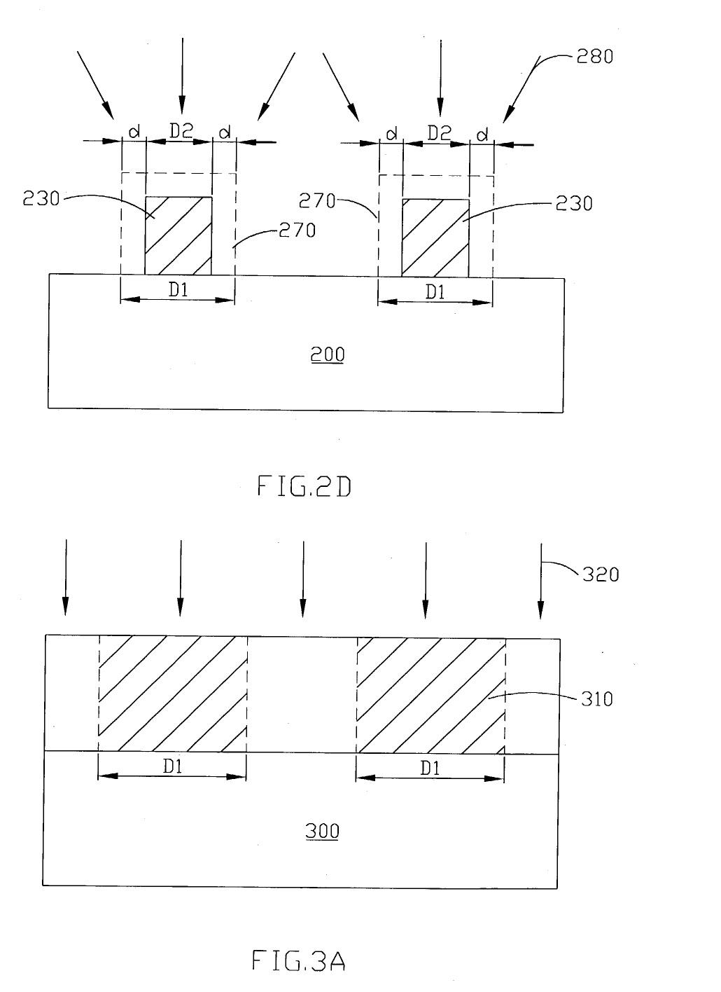

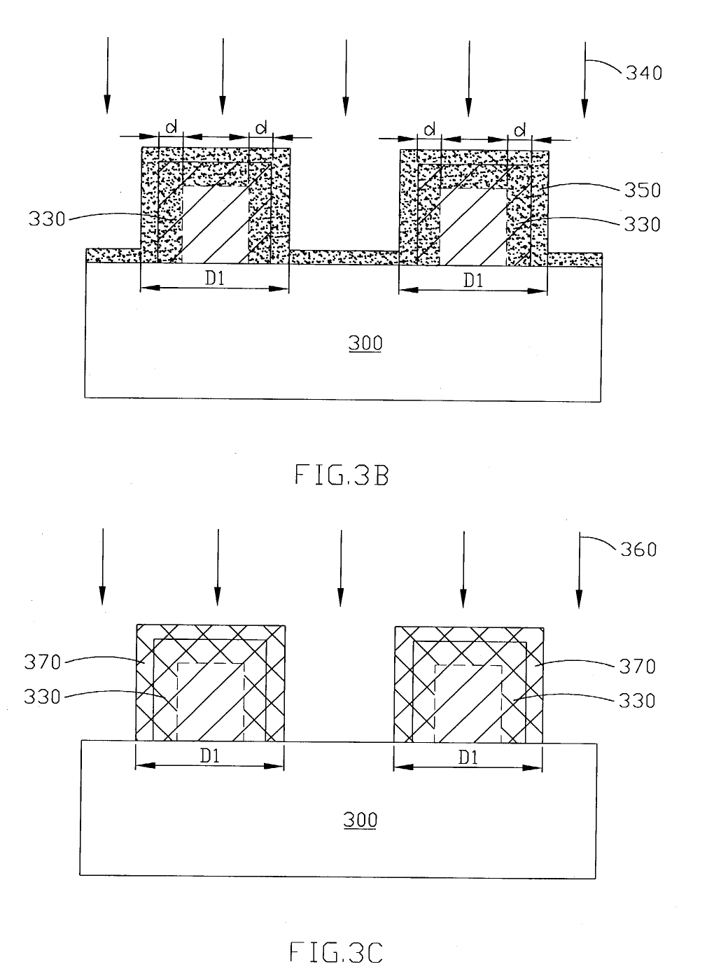

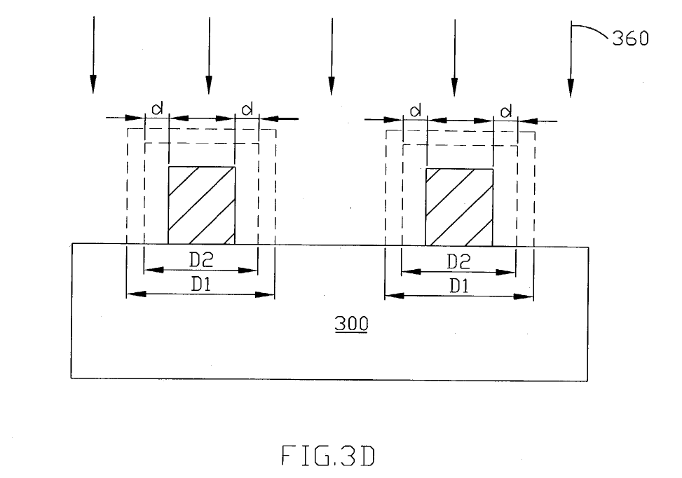

As illustrated in FIG. 3A to FIG. 3D, in the third embodiment of the present invention, first of all, a semiconductor substrate 300 is provided and a photoresist layer 310 having hydrophobic polarity is formed on the semiconductor substrate 300, wherein the photoresist layer 310 comprises a chemical-amplified photoresist material (CAP), such as I-line, deep ultraviolet material (DUV). Then performing an exposure process 320A is to transform the patterns of the mask onto the photoresist layer 310 so as to define a plurality of pattern regions with a first line width D1 in the photoresist layer 310. After defining the plurality of pattern regions, a first developing process 320B is performing to form a plurality of pattern photoresists with the first line width D1 on the semiconductor substrate 300 located on the plurality of pattern regions. Afterward, an acid-process 340 is performed to conform a diffusion layer 350 on the plurality of pattern photoresists 330 and the semiconductor substrate 300, wherein the acid-process 340 comprises a spin-coating process; and further, the acid-based materials utilized in the acid-process 340 can transform the hydrophobic polarity into the hydrophilic polarity within the plurality of pattern photoresists 330, and the diffusion depth d of the acid-based materials in the plurality of pattern photoresists 330 depend on the-diffuse rate of the acid-based materials, and the acid-based materials comprises a fluorine-based acid. Subsequently, a baking process 360 is performed to diffuse the acid-based materials of the acid-process 340 from the diffusion layer 350 into the plurality of pattern photoresists 330 such that the plurality of pattern photoresists 330 chain-react with the acid-based materials therein to transform the hydrophobic polarity into the hydrophilic polarity within the parts of the plurality of pattern photoresists 330 located on the diffusion depth d of the acid-based materials, so as to form a plurality of reaction layers 370 with the hydrophilic polarity on the skin layer of the plurality of pattern photoresists 330, wherein the width of the plurality of reaction layers 370 are increased as the operation temperature and time of the baking process 360 is increased; and further, the optimal time is about between 10 sec to 600 sec and the optimal temperature is about between 50° C. to 200° C. Finally, a second developing process 380 is performed to remove the plurality of reaction layers 370, so as to trim the first line width D1 to a second line width D2 of the plurality of pattern photoresists 230 on the semiconductor substrate 200, wherein the difference in line width between the first line width D1 and the second line width D2 there is the diffusion depth d in the plurality of pattern photoresists 330, wherein the developing process 380 comprises a developer with the hydrophilic polarity. Furthermore, all processes in the third embodiment disclosed as above are performed in the in-situ environment.

In these embodiments of the present invention, as discussed above, this invention can shrink the critical dimension by applying additional material on the photoresist after development, and then baking process is performed for diffusing the acid-based materials into the photoresist so as to change the polarity thereof; and further, the developing process is performed again to remove the additional materials and the polarity change area of photoresist. Therefore, there are the advantages in this invention, such as less complication, cost down, easy to control the shrinkage, improve the line edge roughness, less film loses and enlarge process window. Accordantly, the control window of the critical dimension bias becomes wider and wider. Therefore, the present invention is appropriate for deep sub-micron technology in providing semiconductor devices.

Of course, it is possible to apply the present invention to the process for shrinking the line width of the pattern photoresist, and it is also possible for the present invention to be applied to any process for controlling the critical dimension in the semiconductor process. Furthermore, at the present time, the method of the present invention that utilizes the acid-process and baking process to control the line width of the pattern photoresist has not been applied to concerning shrinking the critical dimension of the pattern photoresist. The method of the present invention is the best process for trimming the pattern photoresist compatible process for deep sub-micron process.

Obviously, many modifications and variations of the present invention are possible in light of the above teachings. It is to be understood that within the scope of the appended claims, the present invention may be practiced other than as specifically described herein.

Although the specific embodiments have been illustrated and described, it will be obvious to those skilled in the art that various modifications may be made without departing from what is intended to be limited solely by the appended claims.

What is claimed is:

1. A method for shrinking the pattern photoresist, the method comprising:
providing a semiconductor substrate that has a pattern photoresist with a first line width thereon;
forming a chemical diffusion layer on said pattern photoresists by using a chemical material;
diffusing said chemical material from said chemical diffusion layer into said pattern photoresist such that said pattern photoresist is reacted with said chemical material by a chemical reaction to form a chemical reaction layer within the skin layer of said pattern photoresist; and
removing said chemical reaction layer to trim said first line width to form a second line width of said pattern photoresist on said semiconductor substrate.

2. The method according to claim 1, wherein the method for diffusing said chemical material comprises an anisotropic diffusion.

3. The method according to claim 1, wherein the diffusion depth of said chemical diffusion layer in said pattern photoresist depends on the diffuse rate of said chemical material.

4. The method according to claim 1, wherein said chemical reaction and said diffusing step is performed by a baking process.

5. The method according to claim 1, wherein the method for removing said chemical reaction layer comprises a developing process.

6. The method according to claim 1, wherein the difference in line width between said first line width and said second line width is the diffusion depth of said chemical diffusion layer in said pattern photoresist.

7. The method according to claim 1, wherein the processes of claim 1 are performed in the in-situ environment.

8. A method for shrinking the pattern photoresist, the method comprising:
providing a semiconductor substrate;
forming a photoresist layer with a first chemical polarity on said semiconductor substrate;
forming a plurality of pattern photoresists with a first line width on said semiconductor substrate by said photoresist layer;
forming a plurality of diffusion layers with a acid-based material on said plurality of pattern photoresists;
diffusing said acid-based material from said plurality of diffusion layers into said plurality of pattern photoresists such that said plurality of pattern photoresists are reacted with said acid-based material by using a chemical reaction to form a plurality of reaction layers having a second chemical polarity within the skin layer of said plurality of pattern photoresists; and
removing said plurality of reaction layers to trim said first line width to form a second line width of said plurality of pattern photoresists on said semiconductor substrate.

9. The method according to claim 8, wherein the method for forming said plurality of pattern photoresists comprises a photolithography process.

10. The method according to claim 8, wherein the method for forming said plurality of diffusion layers comprises an acid-process.

11. The method according to claim 8, wherein said acid-based material can transform said first chemical polarity into said second chemical polarity of said plurality of pattern photoresists.

12. The method according to claim 8, wherein a diffusion depth of said acid-based material in said plurality of pattern photoresists depends on the diffuse rate of said acid-based material.

13. The method according to claim 12, wherein said diffusion depth of said acid-based material in said plurality of pattern photoresists is the difference in line width between said first line width and said second line width.

14. The method according to claim 8, wherein said diffusing step and said chemical reaction is performed by a baking process.

15. The method according to claim 8, wherein the method for removing said plurality of reaction layers comprises a developing process.

16. The method according to claim 15, wherein said developing process comprises a developer with said second chemical polarity.

17. The method according to claim 8, wherein the processes of claim 8 are performed in the in-situ environment.

18. A method for shrinking the pattern photoresist, the method comprising:
providing a semiconductor substrate;
forming a photoresist layer with a hydrophobic polarity on said semiconductor substrate;
performing an exposure process to define a plurality of pattern regions with a first line width in said photoresist layer;
performing a first developing process to form a plurality of pattern photoresists with a first line width on said semiconductor substrate located in said plurality of pattern regions;
performing an acid-process to conform a diffusion layer having an acid-based material on said plurality of pattern photoresists and said semiconductor substrate;
performing a baking process to diffuse said acid-based material from said diffusion layer into said plurality of pattern photoresists such that said plurality of pattern photoresists chain-react with said acid-based material to transform said hydrophobic polarity into a hydrophilic polarity within said plurality of pattern photoresists and form a plurality of reaction layers having said hydrophilic polarity within the skin layer of said plurality of pattern photoresists; and
performing a second developing process to remove said plurality of reaction layers and trim said first line width to form a second line width of said plurality of pattern photoresists on said semiconductor substrate.

19. The method according to claim 18, wherein said photoresist layer comprises a chemical-amplified photoresist material.

20. The method according to claim 18, wherein said acid-process comprises a spin-coating process.

21. The method according to claim 18, wherein said acid-based material comprises a fluorine-based acid.

22. The method according to claim 18, wherein the diffusion depth of said acid-based material in said plurality of pattern photoresists depend on the diffuse rate of said plurality of acid-based materials.

23. The method according to claim 18, wherein said baking process can control the width of said plurality of reaction layers by way of using the time of said baking process.

24. The method according to claim 23, wherein the width of said plurality of reaction layers are increased as the time of said baking process is increased.

25. The method according to claim 23, wherein the optimal time of said baking process is about between 10 sec to 600 sec.

26. The method according to claim 18, wherein said baking process can control the width of said plurality of reaction layers by way of using the temperature of said baking process.

27. The method according to claim 26, wherein the width of said plurality of reaction layers are increased as the temperature of said baking process is increased.

28. The method according to claim 26, wherein the optimal temperature of said baking process is about between 50° C. to 200° C.

29. The method according to claim 18, wherein said developing process comprises a developer with said hydrophilic polarity.

30. The method according to claim 18, wherein the processes of claim 18 are performed in the in-situ environment.
